(19) United States
(12) Patent Application Publication
(10) Pub. No.: US 2021/0126165 A1
(43) Pub. Date: Apr. 29, 2021

(54) OPTICAL DEVICE STRUCTURE AND METHOD FOR MANUFACTURING SAME

(71) Applicant: Nippon Telegraph and Telephone Corporation, Tokyo (JP)

(72) Inventors: Ryo Nakao, Tokyo (JP); Tomonari Sato, Tokyo (JP)

(21) Appl. No.: 17/055,262

(22) PCT Filed: May 13, 2019
(86) PCT No.: PCT/JP2019/018929

§ 371 Date: Nov. 13, 2020

(30) Foreign Application Priority Data
May 22, 2018 (JP) 2018-097678

(51) Int. Cl. H01L 33/44; H01L 33/00

(52) U.S. Cl. CPC H01L 33/44; H01L 2933/0025; H01L 33/0095; H01L 33/0075

(57) ABSTRACT

On a semiconductor substrate, a first insulation layer having a first opening is formed. Next, on the first insulation layer, a second insulation layer having a second opening that is wider than the first opening is formed. Next, from the surface of the semiconductor substrate at the bottom of the first opening, a semiconductor layer for constituting an optical device is formed through the first opening.

### CROSS-REFERENCE TO RELATED APPLICATIONS

This application is a national phase entry of PCT Application No. PCT/JP2019/018929, filed on May 13, 2019, which claims priority to Japanese Application No. 2018-097678, filed on May 22, 2018, which applications are hereby incorporated herein by reference.

### TECHNICAL FIELD

The present invention relates to an optical device structure including a semiconductor layer for configuring an optical device and a production method for the same.

### BACKGROUND

Semiconductors are used as material for electronic devices and optical devices. Many semiconductors used as devices have a layered structure, and are formed on a substrate such as a semiconductor base material or sapphire using a crystal growth device.

Originally, crystal growth was done by lattice-matching to a substrate, but in order to improve productivity and device characteristics, lattice-mismatched growth (heteroepitaxial growth), such as GaN growth on a sapphire substrate or compound semiconductor growth on a Si substrate, has also been employed.

In heteroepitaxial growth, various crystal defects are introduced in the heterointerface, and these defects thread into the layer constituting the semiconductor electronic or optical device (device layer). Since these threading defects degrade the device characteristics, suppressing threading defects is crucial in order to prevent degradation of device characteristics.

A number of techniques for reducing threading dislocation density have been proposed, one of which is epitaxial lateral overgrowth (ELO). In ELO, a mask material such as SiO₂ is deposited on a semiconductor substrate on which heteroepitaxial growth is to be performed to form a mask layer, an opening is formed in a portion of the mask layer, and crystal growth is performed through this opening. In the crystal growth through this opening, by using a growth mode in which the crystal is grown directly above the opening in the mask layer and also so as to cover the mask layer, it becomes possible to suppress propagation of dislocations from the substrate on the mask layer.

### CITATION LIST

### Non-Patent Literature

Non-Patent Literature 1: G. Suryanarayanan et al., “Microstructure of lateral epitaxial overgrown InAs on (100) GaAs substrates”, Applied Physics Letters, vol. 83, no. 10, pp. 1977-1979, 2003.

### SUMMARY

### Technical Problem

However, the surface shape of a semiconductor layer formed on the mask by ELO will not necessarily be flat and parallel to the substrate surface, and will thus not necessarily be suitable when forming, for example, a quantum well structure or a semiconductor device structure (see Non-patent Literature 1). In such cases, the surface of the grown semiconductor layer is flattened through techniques such as chemical mechanical polishing (CMP).

However, in planarization by CMP, controlling the polishing thickness is by no means easy, and problems such as uniformity in the substrate surface and excessive or insufficient polishing of the semiconductor layer easily occur. In addition, while heteroepitaxial growth makes it possible to integrate semiconductors with different lattice constants, it was difficult to realize highly efficient semiconductor optical devices utilizing strong light confinement attained by integration of a semiconductor with an insulation layer having a great difference in refractive index.

Even in ELO utilizing an insulation layer, no structures have been proposed that promise the effect of reducing dislocation density in the insulation layer and achieve a strong light confinement effect utilizing a great refractive index difference. As such, while ELO techniques used in heteroepitaxial growth have the effect of suppressing dislocation density, there are problems in that control of the polishing process is poor, and in that it is difficult to produce highly efficient devices utilizing the optical effects of the insulation layer.

Embodiments of the present invention were made to solve problems like the ones mentioned above, and an object thereof is to make it possible to form a highly efficient optical device using a semiconductor layer formed on a different type of substrate on which an insulation layer is formed.

### Means for Solving the Problem

The optical device structure according to the present invention includes a first insulation layer having a first opening formed on a semiconductor substrate, a second insulation layer formed on the first insulation layer and having a second opening that is wider than the first opening and positioned in a region including the formation region of the first opening, and a semiconductor layer for constituting an optical device, being formed on the surface of the semiconductor substrate exposed by the first opening so as to grow through the first opening and having a different lattice constant than the semiconductor substrate.

### DETAILED DESCRIPTION OF EMBODIMENTS OF THE INVENTION

In the device structure described above, the first insulation layer and second insulation layer are composed of any of SiO₂, SiN, SiOx, SiON, and Al₂O₃, and a thickness b of the second insulation layer need only be formed in a state that satisfies Formula (A) below.

In the optical device structure described above, the semiconductor layer need only be composed of any of InP, GaAs, GaP, AlAs, and GaN, or a compound thereof.

In the optical device structure described above, a thickness a of the first insulation layer need only be formed in a state that satisfies Formula (B) below.

In addition, the production method of the optical device structure according to embodiments of the present invention includes a first step of forming, on a semiconductor substrate, a first insulation layer having a first opening, a second step of forming, on the first insulation layer, a second insulation layer having a second opening that is wider than the first opening and positioned in a region including the formation region of the first opening, a third step of forming a semiconductor growth layer with a different lattice constant than the semiconductor substrate to above the second insulation layer by causing crystal growth from the surface of the semiconductor substrate exposed by the first opening, and a fourth step of forming a semiconductor layer for constituting an optical device having a flat surface forming a plane identical to the surface of the second insulation layer by polishing a portion of the semiconductor growth layer over the second insulation layer.

In the production method of the optical device structure described above, the first insulation layer and second insulation layer are composed of any of SiO₂, SiN, SiOx, SiON, and Al₂O₃, and a thickness b of the second insulation layer need only be formed in a state that satisfies Formula (A) below.

In the production method of the optical device structure described above, the semiconductor layer need only be composed of any of InP, GaAs, GaP, AlAs, and GaN, or a compound thereof.

In the production method of the optical device structure described above, a thickness a of the first insulation layer need only be formed in a state that satisfies Formula (B) below.

$$\begin{matrix}Formula 1 & \\ b < \frac{3}{2 π} \frac{λ}{\sqrt{{n}_{core}^{2} - {n}_{clad}^{2}}} & ( A ) \\ a > \frac{λ}{2 π} \frac{1}{\sqrt{{n}_{core}^{2} - {n}_{clad}^{2}}} \\ Lambda \text{:} wavelength of subject light , {n}_{core} \text{:} refractive index of the semiconductor layer , {n}_{clad} \text{:} refractive index of the first insulation layer & ( B )\end{matrix}$$

### Effects of Embodiments of the Invention

Due to the matters described above, embodiments of the present invention achieve an excellent effect in that a highly efficient optical device can be formed using a semiconductor layer formed on a different type of substrate on which an insulation layer is formed.

### BRIEF DESCRIPTION OF THE DRAWINGS

FIG. 1 is a cross-sectional view showing a configuration of an optical device structure according to an embodiment of the present invention.

FIG. 2 is a cross-sectional view showing another configuration of an optical device structure according to an embodiment of the present invention.

FIG. 3 is a cross-sectional view showing another configuration of an optical device structure according to an embodiment of the present invention.

FIG. 4 is a cross-sectional view showing a configuration of an optical waveguide of an optical device structure according to an embodiment of the present invention.

FIG. 5A is a cross-sectional view showing a state of an intermediate step for describing the production method of an optical waveguide of an optical device structure according to an embodiment of the present invention.

FIG. 5B is a cross-sectional view showing a state of an intermediate step for describing the production method of an optical waveguide of an optical device structure according to an embodiment of the present invention.

FIG. 5C is a cross-sectional view showing a state of an intermediate step for describing the production method of an optical waveguide of an optical device structure according to an embodiment of the present invention.

FIG. 5D is a cross-sectional view showing a state of an intermediate step for describing the production method of an optical waveguide of an optical device structure according to an embodiment of the present invention.

FIG. 5E is a cross-sectional view showing a state of an intermediate step for describing the production method of an optical waveguide of an optical device structure according to an embodiment of the present invention.

FIG. 5F is a cross-sectional view showing a state of an intermediate step for describing the production method of an optical waveguide of an optical device structure according to an embodiment of the present invention.

FIG. 5G is a cross-sectional view showing a state of an intermediate step for describing the production method of an optical waveguide of an optical device structure according to an embodiment of the present invention.

FIG. 5H is a cross-sectional view showing a state of an intermediate step for describing the production method of an optical waveguide of an optical device structure according to an embodiment of the present invention.

### DETAILED DESCRIPTION OF ILLUSTRATIVE EMBODIMENTS

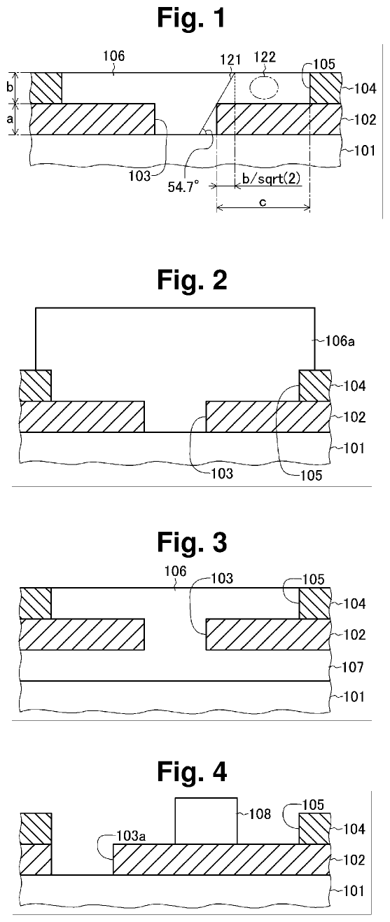

An optical device structure according to an embodiment of the present invention is described below with reference to FIG. 1. This optical device structure includes a first insulation layer 102 formed on a semiconductor substrate 101 and a second insulation layer 104 formed on the first insulation layer 102. The semiconductor substrate 101 is composed of a semiconductor crystal, for example single-crystal silicon, having a diamond structure in which, for example, the main surface is plane (001). Further, the first insulation layer 102 and the second insulation layer 104 need only be composed of, for example, SiO₂, SiN, SiOx, SiON, or Al₂O₃.

The first insulation layer 102 includes a first opening 103. The first opening 103 is formed all the way through the first insulation layer 102. The second insulation layer 104 includes a second opening 105 that is wider than the first opening 103 and positioned in a region including the formation region of the first opening 103. The second opening 105 is formed all the way through the second insulation layer 104. The opening widths of the first opening 103 and the second opening 105 change in a stepped manner when viewed in cross-section. For example, the first opening 103 and the second opening 105 are grooves that extend in a depth direction in FIG. 1. It should be noted that while the first opening 103 is positioned at the center of the width direction of the second opening 105 in FIG. 1, the invention is not limited to this configuration.

The first opening 103 and the second opening 105 are, for example, rectangular as seen in a plan view, and each rectangular opening is oriented parallel or orthogonal to a direction [110. of the crystal of the semiconductor constituting the semiconductor substrate 101. For example, one pair of opposite sides of the plan view rectangle of the first opening 103 and the second opening 105 is oriented parallel to the direction [110. of the crystal of the semiconductor constituting the semiconductor substrate 101, and the other pair of opposite sides is oriented orthogonal to the direction [110. of the crystal of the semiconductor constituting the semiconductor substrate 101.

The first insulation layer 102 having the first opening 103 can be formed by, for example, patterning an insulation film, made by depositing a specific insulation material by a known deposition device, using known lithography and etching techniques. The same applies for the second insulation layer 104 having the second opening 105. In addition, the first opening 103 does not need to be positioned at the center of the second opening 105, but need only be formed at any location in the formation region of the second opening 105. For example, in a cross-sectional view, the stepped portion of the first opening 103 and the second opening 105 may be formed asymmetrically.

Further, the optical device structure according to the present embodiment includes a semiconductor layer 106 for constituting an optical device, the semiconductor layer 106 being formed on the surface of the semiconductor substrate 101 exposed by the first opening 103 so as to grow through the first opening 103 and having a different lattice constant than the semiconductor substrate 101. The semiconductor layer 106 may be composed of a compound semiconductor such as, for example, InP, GaAs, GaP, AlAs, and GaN.

The optical device structure according to the embodiment described above may be formed by polishing, for example, the semiconductor growth layer 106a that has been formed to above the second insulation layer 104 by causing crystal growth from the surface of the semiconductor substrate 101 exposed by the first opening 103 as shown in FIG. 2, using a polishing technique such as chemical mechanical polishing (CMP). The semiconductor growth layer 106a is the layer which will become the semiconductor layer 106, and is composed of a semiconductor having a different lattice constant than the semiconductor substrate 101.

The second insulation layer 104 is composed of a material with a polishing rate that is sufficiently slow compared to that of the semiconductor growth layer 106a. If the polishing rate of the second insulation layer 104 is sufficiently slow, then as the semiconductor growth layer 106a is being polished, polishing will stop when the height (upper surface) of the second insulation layer 104 and the height (upper surface) of the semiconductor growth layer 106a (semiconductor layer 106) are substantially on the same level. As a result, the surface of the second insulation layer 104 and the surface of the semiconductor layer 106 will be in a flat state forming an identical plane, as shown in FIG. 1. In this way, according to the present embodiment, it is easy to control the polishing thickness for forming the semiconductor layer 106. Further, according to the present embodiment, by providing a plurality of optical device structures on the same semiconductor substrate 101, uniformity of the optical device structures in the same substrate plane can be improved.

When determining the layer thickness of the second insulation layer 104, it is preferable that the optical device constituted by the semiconductor layer 106 which will have the same layer thickness as the second insulation layer 104 is single-mode at the wavelength to be used (operating wavelength). In a case where the semiconductor layer 106 constitutes a planar optical waveguide, in order for the optical device to be single-mode in the thickness direction of the core, the thickness b of the second insulation layer 104 should satisfy the relationship described below, wherein the operating wavelength is Lambda, the refractive index of the semiconductor layer 106 is ncore, and the refractive index of the first insulation layer 102 is nclad.

$$\begin{matrix}Formula 2 & \\ b < \frac{3}{2 π} \frac{λ}{\sqrt{{n}_{core}^{2} - {n}_{clad}^{2}}} & ( 1 )\end{matrix}$$

For example, in a case where the operating wavelength is 1.55 μm, the material of the semiconductor layer 106 is InP, and the first insulation layer 102 is made of SiO₂, the approximate thickness b of the second insulation layer 104 will be 0.25 μm or less. Moreover, other possible materials for the first insulation layer 102 and the second insulation layer 104 other than SiO₂ include SiN, SiOₓ, SiON, Al₂O₃, etc., but are not limited to these.

An opening dimension difference c between the first opening 103 and the second opening 105 should be as big as possible in order to prevent dislocation threading. For example, it is known that when the main surface of the semiconductor substrate 101 is plane (001), a dislocation 121 of the semiconductor layer 106 formed by heteroepitaxial growth is easily formed with plane (111) as a slip plane. In this case, since the dislocation 121 will be formed at an angle of 54.7 degrees from the main surface of the semiconductor substrate 101, it could thread from the edge of the first opening 103 to a distance of “b/sqrt(2)”, where “b” is the layer thickness of the second insulation layer 104, as shown in FIG. 1.

In order to avoid formation of a dislocation in this way and provide a light confinement region 122, the edge of the second opening 105 needs to be outwardly distanced from the edge of the first opening 103 by at least as much as shown in Formula (2) below.

$$\begin{matrix}Formula 3 & \\ c > \frac{b}{\sqrt{2}} & ( 2 )\end{matrix}$$

When determining the layer thickness a of the first insulation layer 102, in a case where the semiconductor layer 106 is to be, for example, a low-loss optical waveguide, it is required that leakage of light confined in the semiconductor layer 106 stops within the first insulation layer 102 and does not affect anything below the first insulation layer 102. In a case where the semiconductor layer 106 constitutes a planar optical waveguide, leakage of light into the first insulation layer 102 can be expressed, for example, as in Formula (3) below, with the upper surface of the first insulation layer 102 as the origin point and the substrate vertical direction as the x-axis.

$$\begin{matrix}Formula 4 & \\ a > \frac{λ}{2 π} \frac{1}{\sqrt{{N}^{2} - {n}_{clad}^{2}}} & ( 3 )\end{matrix}$$

However, N is the effective refractive index of a waveguide mode, and the relationship nclad<N<ncore exists. Since the minimum value of a is N to ncore, it is crucial that a satisfies at least the relationship shown in Formula (4) below.

$$\begin{matrix}Formula 5 & \\ a > \frac{λ}{2 π} \frac{1}{\sqrt{{n}_{core}^{2} - {n}_{clad}^{2}}} & ( 4 )\end{matrix}$$

On the other hand, in a case where, for example, an optical waveguide structure is to be made below (on the substrate side of) the first insulation layer 102 separately from the semiconductor layer 106 and the light of the semiconductor layer 106 is to be coupled to the substrate side optical waveguide, it is necessary to satisfy the conditions represented by the reversed inequality sign in Formula (3).

In addition, other than the structure in which the first insulation layer 102 is formed in contact with the semiconductor substrate 101, it is also possible to, as shown in FIG. 3, form a semiconductor layer 107 on the semiconductor substrate 101 and form the aforementioned structure consisting of the first insulation layer 102, the second insulation layer 104, and the semiconductor layer 106 on the semiconductor layer 107. In this way, the first insulation layer 102 may be formed at a position separate from the semiconductor substrate 101 by a specific distance.

Next, the optical waveguide constituted by the optical device structure according to embodiments of the present invention is described with reference to FIG. 4. FIG. 4 shows a cross-section of a plane vertical to the optical waveguide direction. This optical waveguide includes a core layer 108 composed of a semiconductor on the first insulation layer 102 within the second opening 105. The core layer 108 constitutes an optical waveguide in which the core layer 108 is a light confinement region. The core layer 108 is formed thicker (higher) than the second insulation layer 104. It should be noted that in this example, the first opening 103a is formed at a position offset from the center of the second opening 105 in a plan view.

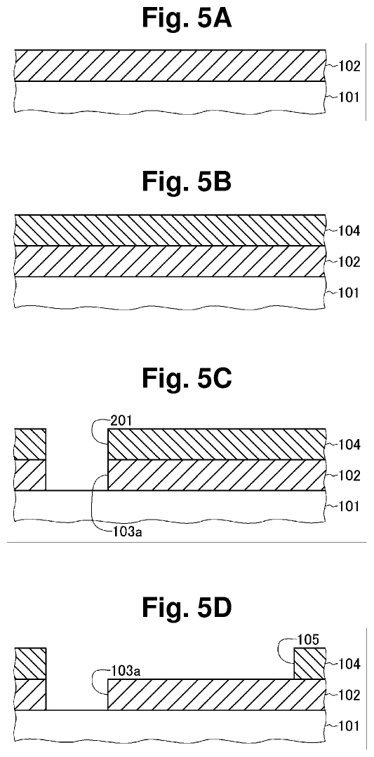

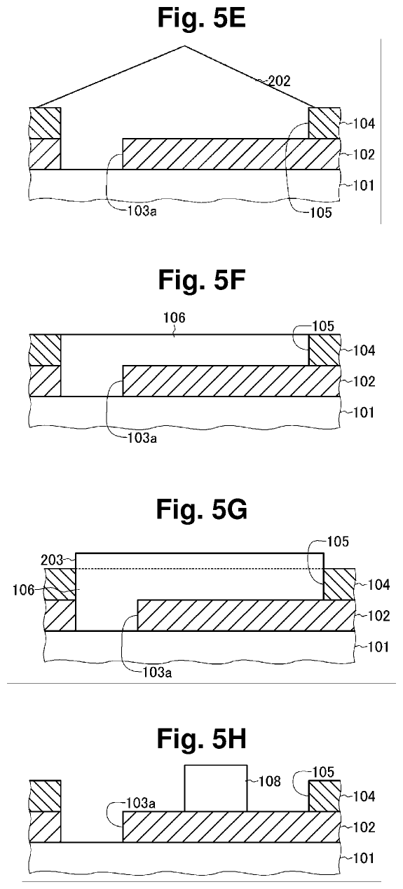

The production method of the optical device structure (optical waveguide) described using FIG. 4 is described below with reference to FIGS. 5A to 5H.

First, as shown in FIG. 5A, the first insulation layer 102 is formed on the semiconductor substrate 101. The first insulation layer 102 may be formed by, for example, depositing SiN using a sputtering method or chemical vapor deposition (CVD) method. Next, as shown in FIG. 5B, the second insulation layer 104 is formed on the first insulation layer 102. The second insulation layer 104 may be formed by, for example, depositing SiO₂ using a sputtering method or CVD method.

Next, an opening 201 is formed in the second insulation layer 104 as shown in FIG. 5C by patterning using well-known photolithography and etching techniques, and a first opening 103a is consecutively formed in the first insulation layer 102 (First Step). Moreover, after each opening has been formed, the mask pattern used for etching is removed.

Next, the second opening 105 is formed in the second insulation layer 104 as shown in FIG. 5D by patterning using well-known photolithography and etching techniques (Second Step). Here, it is preferable that the etching process is performed under the condition of selectively etching SiO₂ with respect to SiN. For example, the second opening 105 may be formed by selectively etching SiO₂ through wet etching using an HF etchant. Moreover, after the second opening 105 has been formed, the mask pattern used for etching is removed.

Next, a semiconductor growth layer 202 is formed to above the second insulation layer 104, for example, by causing crystal growth of InP using a crystal growth method such as a well-known metalorganic chemical vapor deposition method, from the surface of the semiconductor substrate 101 exposed by the first opening 103a (Third Step). InP is a semiconductor with a different lattice constant than the silicon constituting the semiconductor substrate 101.

Next, the portion of the semiconductor growth layer 202 above the second insulation layer 104 is polished. The semiconductor growth layer 202 is polished, for example, under conditions where the InP is selectively polished through CMP. As shown in FIG. 5F, this results in the formation of the semiconductor layer 106 for constituting an optical device having a flat surface forming a plane identical to the surface of the second insulation layer 104 (Step 4).

Next, as shown in FIG. 5F, a regrowth layer 203 consisting of InP is formed on the semiconductor layer 106 through regrowth or the like. Next, a core layer 108 is formed as shown in FIG. 5H by patterning the semiconductor layer 106 having the regrowth layer 203 formed thereupon using well-known lithography and etching techniques, and a planar optical waveguide or channel optical waveguide constituted by the core layer 108 is formed.

As previously mentioned, the dislocation of the semiconductor layer 106 formed by heteroepitaxial extending from the semiconductor substrate 101 at the bottom of the first opening 103a threads from the edge of the first opening 103 to a distance of approximately “b/sqrt(2)”, where “b” is the layer thickness of the second insulation layer 104. By forming the core layer 108 at a position farther away from the edge of the first opening 103 than this distance, no thread dislocation will be formed (propagated) in the core layer 108. It should be noted that instead of the regrowth layer 203, a quantum well structure (multiquantum well structure) may be formed to make an optical waveguide (optical device) with an added functional structure.

As described above, according to embodiments of the present invention, a second insulation layer having a second opening that is wider than a first opening is formed on a first insulation layer having the first opening, and a semiconductor layer for constituting an optical device is formed on the surface of a semiconductor substrate through the first opening, which makes it possible to form a highly efficient optical device using a semiconductor layer formed on a different type of substrate on which an insulation layer is formed.

Moreover, it should be readily apparent that the present invention is not limited to the embodiments described above, but that a person of ordinary skill in the art to which the invention pertains could implement several variants and combinations within the technical concept of the present invention.

### REFERENCE SIGNS LIST

101 Semiconductor substrate
102 First insulation layer
103 First opening
104 Second insulation layer
105 Second opening
106 Semiconductor layer
121 Dislocation
122 Light confinement region.

1.-8. (canceled)

9. A production method for an optical device structure, the method comprising:
forming, on a semiconductor substrate, a first insulation layer having a first opening;
forming, on the first insulation layer, a second insulation layer having a second opening that is wider than the first opening and positioned in a region including the first opening;
forming a semiconductor growth layer by crystal growing from a surface of the semiconductor substrate exposed by the first opening to above the second insulation layer, wherein the semiconductor growth layer has a different lattice constant than the semiconductor substrate; and
polishing a portion of the semiconductor growth layer above the second insulation layer to planarize a surface of the semiconductor growth layer with the second insulating layer and define an optical device in the first opening.

10. The production method for the optical device structure according to claim 9, wherein:
the first insulation layer and the second insulation layer each comprise SiO₂, SiN, SiOₓ, SiON, or Al₂O₃; and
a thickness b of the second insulation layer is formed in a state that satisfies Formula (A) below:
$$b < \frac{3}{2 π} \frac{λ}{\sqrt{{n}_{core}^{2} - {n}_{clad}^{2}}} , \qquad ( A )$$
wherein λ represents a wavelength of subject light, n_{core} represents a refractive index of the semiconductor growth layer, and n_{clad} represents a refractive index of the first insulation layer.

11. The production method for the optical device structure according to claim 9, wherein the semiconductor growth layer is composed of InP, GaAs, GaP, AlAs, GaN, or a compound thereof.

12. The production method for the optical device structure according to claim 9, wherein:
a thickness a of the first insulation layer is formed in a state that satisfies Formula (B) below:
$$a > \frac{λ}{2 π} \frac{1}{\sqrt{{n}_{core}^{2} - {n}_{clad}^{2}}} , \qquad ( B )$$
wherein λ represents a wavelength of subject light, n_{core} represents a refractive index of the semiconductor growth layer, and n_{clad} represents a refractive index of the first insulation layer.

13. An optical device structure comprising:
a first insulation layer on a semiconductor substrate, the first insulation layer having a first opening;
a second insulation layer on the first insulation layer and having a second opening that is wider than the first opening, the second opening being positioned in a region including the first opening; and
a semiconductor layer for constituting an optical device, the semiconductor layer being disposed on a surface of the semiconductor substrate exposed by the first opening so as to extend through the first opening, and the semiconductor layer having a different lattice constant than the semiconductor substrate.

14. The optical device structure according to claim 13, wherein:
the first insulation layer and the second insulation layer each comprise SiO₂, SiN, SiOₓ, SiON, or Al₂O₃; and
a thickness b of the second insulation layer is formed in a state that satisfies Formula (A) below:
$$b < \frac{3}{2 π} \frac{λ}{\sqrt{{n}_{core}^{2} - {n}_{clad}^{2}}} , \qquad ( A )$$
wherein λ represents a wavelength of subject light, n_{core} represents a refractive index of the semiconductor layer, and n_{clad} represents a refractive index of the first insulation layer.

15. The optical device structure according to claim 13, wherein the semiconductor layer comprises InP, GaAs, GaP, AlAs, GaN, or a compound thereof.

16. The optical device structure according claim 13, wherein:
a thickness a of the first insulation layer is formed in a state that satisfies Formula (B) below:
$$a > \frac{λ}{2 π} \frac{1}{\sqrt{{n}_{core}^{2} - {n}_{clad}^{2}}} , \qquad ( B )$$
wherein λ represents wavelength of subject light, n_{core} represents a refractive index of the semiconductor layer, and n_{clad} represents a refractive index of the first insulation layer.
